(19) United States
(12) Patent Application Publication
(10) Pub. No.: US 2007/0284598 A1
(43) Pub. Date: Dec. 13, 2007

(54) Semiconductor Light Emitting Device

(76) Inventors: Yukio Shakuda, Kyoto-shi (JP); Toshio Nishida, Kyoto-shi (JP); Masayuki Sonobe, Kyoto-shi (JP)

Correspondence Address: RABIN & Berdo, PC, 1101 14TH STREET, NW, SUITE 500, WASHINGTON, DC, 20005, US

(21) Appl. No.: 11/661,631

(22) PCT Filed: Sep. 1, 2005
(86) PCT No.: PCT/JP05/16026

§ 371 Date: Mar. 1, 2007

(30) Foreign Application Priority Data
Sep. 2, 2004 (JP) 2004-255802

(51) Int. Cl. H01L 33/00

(52) U.S. Cl. 257/93; 257/E33.012

(57) ABSTRACT

There is provided a highly reliable semiconductor light emitting device in which disconnection of wires does not occur in case that a semiconductor light emitting device capable of being used in place of incandescent lamps or fluorescent lamps is formed in a monolithic type by forming a plurality of light emitting units on one substrate. A plurality of light emitting units (1) are formed by electrically separating a semiconductor lamination portion (17) which is so formed on a substrate (11) as to form a light emitting layer, and the light emitting units (1) are respectively connected in series and/or parallel by wiring films (3). For obtaining the light emitting units (1) from the semiconductor lamination portion a separation groove (17a) and an insulation film (21) deposited in the separation groove (17a) are formed in the semiconductor lamination portion (17). The separation groove (17a) is formed in such a position that the surfaces of the semiconductor lamination portion (17) on both sides of the separation groove (17a) are in the substantially same plane, and the wiring film (3) is formed on the separation groove (17a) through the insulating film (21).

### FIELD OF THE INVENTION

The present invention relates to a semiconductor light emitting device in which a plurality of light emitting units are formed on a substrate and connected in series and/or parallel, and which can be used for light sources in place of incandescent lamps or fluorescent lamps used with commercial AC power sources of a voltage of, for example, 100 V. More particularly, the present invention relates to a semiconductor light emitting device which has a structure in which disconnection of a wiring film caused by a separation groove separating each of the light emitting units electrically hardly occurs, while connecting the plurality of light emitting units to each other with the wiring film provided on a top surface side of a semiconductor lamination portion.

### BACKGROUND OF THE INVENTION

Being accompanied with developing blue light emitting diodes (LEDs), the LEDs are lately used for light sources of displays or traffic signals and furthermore become to be used in place of incandescent lamps or fluorescent lamps. As it is preferable that the LEDs can be operated simply with AC driving of 100 V or the like in case that the LEDs are used in place of the incandescent lamps or the fluorescent lamps, as shown, for example, in FIG. 11, a structure in which the LEDs connected in series and/or parallel are connected to an AC power source 71 is known well. Here, S represents a switch (cf. for example PATENT DOCUMENT 1).

On the other hand, integrating these LEDs connected in series and/or parallel into a monolithic type has been performed (cf. for example PATENT DOCUMENT 2). In a structure shown in FIG. 12, for example, a semiconductor lamination portion is formed by, laminating, on a sapphire substrate 60, an i-GaN layer 61, an n-GaN contact layer 62, an n-AlGaN clad layer 63, an active layer 64 formed with an InGaN multi quantum well, a p-AlGaN clad layer 65, and a p-GaN contact layer 66 are laminated in order. And, followed, etching a part of the semiconductor lamination portion so as to expose the n-GaN contact layer 62, forming a groove 70 by etching a border portion of adjacent LEDs up to the i-GaN layer 61, depositing an SiO₂ film 67 in the groove 70, forming a transparent electrode 68 on the p-GaN contact layer 66, and forming a metal electrode 69 so as to connect the n-GaN contact layer 62 and the transparent electrode 68. And here it is also disclosed that the LEDs are connected to the AC power source 71 by connecting each of metal electrodes to a first wire connecting to the power source and a second wire connecting to the power source wire alternatively and are connected in parallel with reverse direction one by one.

PATENT DOCUMENT 1: Japanese Patent Application Laid-Open No. HEI10-083701 (FIG. 3)

PATENT DOCUMENT 2: Japanese Patent Application Laid-Open No. 2000-101136 (FIG. 6)

### DISCLOSURE OF THE INVENTION

### Problem to be Solved by the Present Invention

As described above, a light emitting device of a monolithic type with a plurality of LEDs connected in series and/or parallel is formed by forming a separation groove to separate electrically each of light emitting units after laminating semiconductor layers on the substrate, by embedding an insulating film in the separation groove, and by forming metal electrodes thereon connect adjacent light emitting units. In this case, from the view points of using a sapphire substrate for a substrate, and connecting each of the light emitting units on an upper side with the wiring film or the like, an electrode to be connected to a conductivity type semiconductor layer of a lower layer of the semiconductor lamination portion is formed connected to an exposed semiconductor layer of the lower layer by etching and removing a part of the semiconductor lamination portion. Therefor, in the above-described separation groove, the separation groove 70 is formed by etching further only border parts subsequently to etching for exposing the lower layer. As a result of this, as shown in FIG. 12, a metal electrode 69 has a vertical rising part from an n-GaN contact layer 62 of the lower layer to a transparent electrode 68 provided on a surface of the semiconductor lamination portion.

Although a level difference of semiconductor layers of the lower layer and the upper layer of the semiconductor lamination portion is approximately 0.4 to 1 μm, there arises a problem of occasional disconnections caused by poor step-coverage because of very steep rising of the wiring film, very thin thickness of approximately 0.2 μm of the wiring film, probable caving of the wiring film in the separation groove 70 having a depth of 3 to 6 μm, or the like. This problem becomes more serious if the number of the light emitting units increases. Especially, in a case of a plenty of light emitting units connected in series, if disconnection occurs at one light emitting unit of all, there arises very serious problem such that all light emitting units connected to a part of a series connection can not operate.

The present invention is directed to solve the above-described problems and an object of the present invention is to provide a highly reliable semiconductor light emitting device in which disconnection of wires does not occur in case that a semiconductor light emitting device capable of being used in place of incandescent lamps or fluorescent lamps is formed in a monolithic type by forming a plurality of light emitting units on one substrate.

Another object of the present invention is to provide a semiconductor light emitting device having a structure which secures spaces for wiring and for disposing accessory parts while improving reliability of wiring.

Still another object of the present invention is to provide a semiconductor light emitting device having a structure in which flickering can be inhibited while having a period in which light is not emitted in an alternative current drive and in which an afterglow can be used after being switched off.

Still another object of the present invention is to provide a semiconductor light emitting device having a structure in which even if defects such as a short circuit or the like occur in a part of the plurality of light emitting units, a left part can operate as a light emitting device.

Still another object of the present invention is to provide a semiconductor light emitting device having a structure in which a break down hardly occurs while a plurality of light emitting units are connected in series and/or parallel even if surges or the like enter.

Still another object of the present invention is to provide a semiconductor light emitting device which has an excellent efficiency (external quantum efficiency) of taking light out by avoiding light blocking caused by electrodes or wiring even in case of forming a wiring film forming a series and/or parallel connection at a radiation surface side of the emitted light.

### Means for Solving the Problem

A semiconductor light emitting device includes: a substrate; a semiconductor lamination portion formed on the substrate by laminating semiconductor layers so as to form a light emitting layer; a plurality of light emitting units formed by separating the semiconductor lamination portion electrically into a plurality of units, each of the plurality of light emitting units having a pair of electric connecting portions which are connected to a pair of conductivity type layers of the semiconductor lamination portion, respectively; and wiring films which are connected to the electric connecting portions for connecting each of the plurality of light emitting units in series and/or parallel, wherein electrical separation to form the plurality of light emitting units is formed by a separation groove formed in the semiconductor lamination portion and by an insulating film embedded in the separation groove, wherein the separation groove is formed at a place where surfaces of the semiconductor lamination portions in both sides of the separation groove are in a substantially same plane, and wherein the wiring film is formed above the separation groove through the insulating film.

Here, the substantially same plane does not mean a perfectly same plane, but means surfaces whose level difference is within a level of not raising a problem of a step-coverage caused by the level difference during forming the wiring film and means a level difference of both surfaces is approximately 0.3 μm or less in the concrete. In addition, the electric connecting portion means a metal electrode, a light transmitting conductive layer or the like provided to obtain an ohmic contact with a semiconductor layer, and means a connecting portion formed so as to be connected electrically to the wiring film.

Concretely, the electric connecting portions to the pair of conductivity type layers are formed by an upper electrode provided so as to connect to a first conductivity type semiconductor layer of an upper layer side of the semiconductor lamination portion, and a lower electrode provided so as to connect to a second conductivity type semiconductor layer of a lower layer exposed by removing a part of the semiconductor lamination portion by etching, wherein each of the surfaces of the semiconductor lamination portions in both sides of the separation groove is a semiconductor layer of the upper layer side. It is preferable to form so that a thickness of the lower electrode is thicker than that of the upper electrode.

In addition, the electric connecting portions to the pair of conductivity type layers may be formed by an upper electrode provided so as to connect to a first conductivity type semiconductor layer of an upper layer side of the semiconductor lamination portion, and a lower electrode provided so as to connect to a second conductivity type semiconductor layer of a lower layer exposed by removing a part of the semiconductor lamination portion by etching, wherein each of the surfaces of the semiconductor lamination portions in both sides of the separation groove is a semiconductor layer of a lower layer on which the lower electrode is provided, wherein a dummy region is formed between a first light emitting unit provided with the lower electrode, and a second light emitting unit provided with the upper electrode to be connected to the lower electrode of the first light emitting unit through the separation groove with the wiring film, and the dummy region has an inclined surface which is formed from the semiconductor layer of the lower layer to the semiconductor layer of the upper layer, and wherein the wiring film to connect the lower electrode and the upper electrode is formed on the inclined surface.

It is preferable that a second separation groove is formed at a portion where both surfaces of the semiconductor lamination portions intervening the second separation groove are in the substantially same plane in an opposite side of the dummy region to the separation groove, thereby the reliability can be improved with thanks to separating electrically by the second separation groove even in a case that the first light emitting unit and the second light emitting unit are not separated electrically perfectly because of inaccuracy of forming the separation groove.

The semiconductor lamination portion is made of nitride semiconductor and a light color conversion member converting a wavelength of light emitted in the light emitting layer to white light is provided at least at a light emitting surface side (a surface side radiating light emitted) of the semiconductor lamination portion.

By connecting the plurality of sets of the light emitting units in series so as to be operated with commercial electric power sources, each of the sets being formed by connecting the electric connecting portions connected to the pair of conductivity type layers of one light emitting unit to electric connecting portions of the other light emitting unit in parallel so as to be reversely connected to each other, the light emitting device can be used by connecting to a commercial electric power source such as an alternative current electric power source of 100 V or the like.

Although blinking is repeated by switching on and off the light emitting unit for every half wave in an alternative current operation, flickering by switching on and off is not noticeable by providing a fluorescent material having an afterglow time of 10 msec or more and 1 sec or less at the light emitting surface side of the plurality of light emitting units, because emitting light continues for approximately ten milliseconds or more after switching off, and a stable light emitting device can be obtained. Further, by using a fluorescent material converting a wavelength of light emitted in the light emitting unit to a predetermined wavelength, a desired light color such as white or the like can be obtained with a LED of one light color such as a light of blue color, ultra violet or the like.

By providing a phosphorescent material, which absorbs and stores light from a primary light source and emits the stored light, having an afterglow time of 1 sec or more at the light emitting surface side of the plurality of light emitting units, emitting light can continued even after electric power source to the light emitting unit is shut off, and the light emitting device can be used as emergency lights at a time of power failure.

The semiconductor lamination portion is formed on a light transmitting substrate, a back surface of the substrate is a surface from which light emitted in the light emitting layer is taken out, and a light color conversion member converting a wavelength of the light emitted in the semiconductor lamination portion made of semiconductor nitride to a white light, and at least one of a fluorescent material having an afterglow time of 10 msec or more and 1 sec or less and a phosphorescent material having an afterglow time of 1 sec or more may be provided on the back surface of the substrate.

By connecting a fuse element to each of the groups of the light emitting units connected in series, other groups of the light emitting units can be preferably operated without any abnormality in case that the one of the plurality of groups of light emitting units connected in parallel is shortened.

By connecting a capacitor absorbing surges in parallel between a pair of electrode pads, which is connected to an external electric power source, of the plurality of the light emitting units connected in series and/or parallel, the light emitting units can be preferably protected even if surges enter.

By connecting an inductor absorbing surges in series between a pair of electrode pads which are connected to an external electric power source of the plurality of the light emitting units connected in series and/or parallel, the light emitting units can be also protected even if surges enter. The inductor may be formed by forming an inductor element between each of the light emitting units or by arranging the light emitting units so that each of the light emitting units forms a whirl.

It is preferable that at least a part of the wiring film, which is formed on or above a surface of a semiconductor layer of a conductivity type connected to the upper electrode, is formed by a light transmitting conductive film, because light can be taken out effectively without increasing a series resistance of the wiring.

### EFFECT OF THE INVENTION

By the present invention, in case that a semiconductor light emitting device of a monolithic type which can be operated with a commercial electric power source of, for example, 100 V is formed by dividing a semiconductor lamination portion into a plurality of light emitting units and by connecting between each of the light emitting units in series or parallel with a wiring film, since a separation groove separating each of the light emitting units is formed at a place where both surfaces of the semiconductor lamination portions in both sides of the separation groove are in a substantially same plane, there can be solved such problems as disconnection of the wiring film by a level difference caused by the separation groove and as less reliability of thin thickness even if the disconnection does not occur.

Namely, in the wiring film connecting between the light emitting units in series or parallel, since an electric connecting portion (which means a portion where the wiring film contacts to the semiconductor layer directly or through other conductor layer in an ohmic contact, and hereinafter referred to simply as electrode) connected to a semiconductor layer of a lower layer is at a low position, and an electrode connected to a semiconductor layer of an upper layer is at a high position, a level difference occurs in connecting the both electrode. In addition, when the separation groove is formed in order to separate electrically adjacent light emitting units, it is efficient to form the separation groove at a portion of a boarder from a surface of an exposed semiconductor layer of the lower layer. Therefor, since a large level difference is usually formed at the separation groove and since at the same time the separation groove and an exposed portion of the lower layer are etched successively and widely when viewing from a surface of the semiconductor lamination portion, a level difference to the surface of the semiconductor lamination portion can no be eliminated even if an insulating film is formed. Then, when the wiring film is formed along the level difference stepping over the separation groove, there exists a problem such that the wiring film is easy to break because of thin thickness of the wiring film at a corner of the level difference. However, by the present invention, since the separation groove is formed at a place where surfaces of the semiconductor layers are in a substantially same plane, at least a surface side of the separation groove is almost filled up when forming the insulating film, even if some recess occurs, by forming a very narrow groove having a width capable of obtaining electrical insulation, of, for example, approximately 1 μm. As a result, the wiring formed thereon hardly has a level difference at a portion over the separation groove and does not raise problems such as disconnection and thin thickness of the wiring film, such as a step-coverage trouble.

In this case, although there exists a difference in height between a pair of electrodes, it becomes not necessary to form the wiring film at a portion of the level difference for example, by forming a lower electrode thick, or by forming a dummy region at a part of the semiconductor lamination portion and forming an inclined surface at the dummy region, and the problem caused by step-coverage does not occur.

### BRIEF DESCRIPTION OF THE DRAWINGS

FIG. 1 is a cross-sectional view explaining one embodiment of a semiconductor light emitting device according to the present invention;

FIG. 2 is a cross-sectional view explaining another embodiment of a semiconductor light emitting device according to the present invention;

FIG. 3 is a figure showing an example of arranging light emitting units of the light emitting device according to the present invention;

FIG. 4 is a figure showing an equivalent circuit of FIG. 3;

FIG. 5 is a figure showing an example of an application of the semiconductor light emitting device according to the present invention;

FIG. 6 is a figure showing an example of another application of the semiconductor light emitting device according to the present invention;

FIG. 7 is a figure showing an example of still another application of the semiconductor light emitting device according to the present invention;

FIG. 8 is a figure showing an example of still another application of the semiconductor light emitting device according to the present invention;

FIG. 9 is a figure showing an example of still another application of the semiconductor light emitting device according to the present invention;

FIG. 10 is a figure showing an example of still another application of the semiconductor light emitting device according to the present invention;

FIG. 11 is a figure showing one of a conventional circuit of an illumination device formed by using LEDs;

FIG. 12 is a figure showing one of a conventional structure of an illumination device formed by using LEDs.

### EXPLANATION OF LETTERS AND NUMERALS

1: light emitting unit
3: wiring film
4: electrode pad
5: dummy region
6: fluorescent film
7: phosphorescent glass film
8: fuse element
9: capacitor
10: inductor
11: substrate
13: high temperature buffer layer
14: n-type layer
15: active layer
16: p-type layer
17: semiconductor lamination portion
17a: separation groove
18: light transmitting conductive layer
19: p-side electrode (upper electrode)
20: n-side electrode (lower electrode)
21: insulating film

### THE BEST EMBODIMENT OF THE PRESENT INVENTION

An explanation will be given below of a semiconductor light emitting device according to the present invention in reference to the drawings. As an explanatory cross-sectional view of one embodiment is shown, the semiconductor light emitting device according to the present invention is formed by forming a semiconductor lamination portion 17 on the substrate 11 by laminating semiconductor layers so as to form a light emitting layer, by forming a plurality of light emitting units 1 by separating the semiconductor lamination portion 17 electrically into a plurality of units 1, each of which has a pair of electric connecting portions (electrode 19 and 20) which are connected to a pair of conductivity type layers of the semiconductor lamination portion, respectively, and by connecting each of the plurality of light emitting units 1 in series and/or parallel with wiring films 3. In the present invention, a structure of electrically separating the plurality of light emitting units 1 is characterized in that a separation groove 17a is formed in the semiconductor lamination portion 17 and an insulating film 21 is deposited in the separation groove 17a, and that the separation groove 17a is formed at a place where surfaces of the semiconductor lamination portions 17 in both sides of the separation groove 17a are in a substantially same plane, and the wiring film 3 is formed above the separation groove 17a through the insulating film 21.

In the example shown in FIG. 1, a light emitting device radiating white light is formed by forming the light emitting unit 1 (hereinafter, referred to as simply “LED”, too) emitting blue light laminated with the nitride semiconductor and by depositing a light color conversion member, not shown in figures, like, for example, a fluorescent material of YAG (Yttrium Aluminum Garnet), a fluorescent material of Sr—Zn—La or the like. Therefore, the semiconductor lamination portion is formed by laminating nitride semiconductor layers. However, white light can be obtained by forming light emitting units of three primary colors, red, green and blue, too, and a light emitting portion with a desired light color can be also formed, and white light is not always necessary.

Here, the nitride semiconductor means a compound of Ga of group III element and N of group V element or a compound (nitride) in which a part or all of Ga of group III element substituted by other element of group III element like Al, In or the like and/or a part of N of group V element substituted by other element of group V element like P, As or the like.

As a sapphire (single crystal Al₂O₃) or a SiC is generally used for the substrate 11 in case of laminating the nitride semiconductor, sapphire (single crystal Al₂O₃) is used in an example shown in FIG. 1. But a substrate is chosen from view point of a lattice constant or a thermal expansion coefficient depending upon semiconductor layers to be laminated on.

For example, the semiconductor lamination portion 17 laminated on the sapphire substrate 11 is formed by laminating following layers in order: a low temperature buffer layer 12 made of GaN and having a thickness of approximately 0.005 to 0.1 μm; a high temperature buffer layer 13 made of un-doped GaN and having a thickness of approximately 1 to 3 μm; an n-type contact layer 14 made of an n-type GaN doped with Si formed thereon, having a thickness of approximately 1 to 5 μm, a barrier layer (a layer with a large band gap energy) made of an n-type AlGaN based compound semiconductor, or the like; an active layer 15 which has a structure of a multiple quantum well (MQW) formed in a thickness of approximately 0.05 to 0.3 μm by laminating 3 to 8 pairs of well layers made of a material having a band gap energy lower than that of the barrier layer, for example In_{0.13}Ga_{0.87}N and having a thickness of 1 to 3 nm, and barrier layers made of GaN and having a thickness of 10 to 20 nm; and a p-type layer 16 formed with a p-type barrier layer (a layer with a large band gap energy) made of a p-type AlGaN based compound semiconductor and the contact layer made of a p-type GaN, and having a thickness of approximately 0.2 to 1 μm in total.

In an example shown in FIG. 1, the high temperature buffer layer 13 is formed with GaN which is un-doped and semi-insulating. In case that the substrate is made of an insulating substrate like sapphire, it is not always necessary for the high temperature buffer layer to be semi-insulating because there is no problem if the separation groove is etched up to the substrate as described later, but the un-doped layer is preferable because a crystal structure of the semiconductor layer laminated on that is superior and further, by providing with semi-insulating semiconductor layers, the electrical separation can be obtained without etching up to the substrate surface when each of the light emitting units is separated. And in case that the substrate 11 is made of a semiconductor substrate like SiC, it is necessary to form the high temperature buffer layer 13, un-doped and semi-insulating, for separating adjacent light emitting portions electrically in order to make each of light emitting units independent.

The n-type layer 14 and the p-type layer 16 contain two kinds of the barrier layer and the contact layer in the above-described example, but only a GaN layer can be used sufficiently, although it is preferable with an aspect of carrier confinement effect to form a layer including Al at a side of the active layer 6. And, these can be formed with other nitride semiconductor layers or other semiconductor layers can be interposed. Although, in this example, a double hetero structure is shown in which the active layer 15 is sandwiched by the n-type layer 14 and the p-type layer 16, a structure of a p-n junction can be used in which the n-type layer and the p-type layer are directly joined. Further, although a p-type AlGaN based compound layer is formed directly on the active layer 15, an un-doped AlGaN based compound layer of approximately several nm thicknesses can be laminated on the active layer 15. Thereby, a leakage caused by a contact of the p-type layer and the n-type layer can be avoided while embedding pits created in the active layer 15 by forming a pit-creating layer under the active layer 15.

The light transmitting conductive layer 18 which is formed with for example ZnO or the like and makes an ohmic contact with the p-type semiconductor layer 16 is formed in a thickness of approximately 0.01 to 0.5 μm on the semiconductor lamination portion 17. A material of this light transmitting conductive layer 18 is not limited to ZnO, ITO (Indium Tin Oxide) or a thin alloy layer of Ni and Au having a thickness of approximately 2 to 100 nm can be used and diffuse current to whole part of a chip while transmitting light. The separation groove 17a is formed by removing a part of the semiconductor lamination portion 17 by etching so as to expose the n-type layer 14, and by further etching in the vicinity of an exposed portion of the n-type layer 14 parting by an interval d. This spaced part is a dummy region 5 not contributing to light emitting (portion of a length L1) and the interval d is set in a range of approximately 1 to 50 μm depending on a purpose because the region can be used for a space for making a heat dispersion portion or wiring as described later. The separation groove 17a is formed by a dry etching technique or the like, in a narrow width which electrical separation can be achieved, approximately 0.6 to 5 μm, for example approximately 1 μm (in a depth of approximately 5 μm).

Thereafter, a p-side electrode (upper electrode) 19 is formed on a part of a surface of the light transmitting conductive layer 18 with a lamination structure of Ti and Au, and an n-side electrode (lower electrode) 20 for a ohmic contact is formed on the n-type layer 14 exposed by removing a part of the semiconductor lamination portion 17 by etching with a Ti—Al alloy. In an example shown in FIG. 1, the lower electrode 20 is formed in a thickness of approximately 0.4 to 0.6 μm so as to be as almost high as the upper electrode 19 is. However, the lower electrode 20 is not necessary to be formed in the almost same height to the upper electrode 19, but may be in a usual height, since level difference is not formed so much because the wiring film 3 is deposited on the lower electrode 20 by evaporation or the like. On the other hand, as reliability of the wiring film is improved when the thickness of the lower electrode 20 is thicker than that of the upper electrode 19, the lower electrode 20 is preferably as almost high as the upper electrode 19 is. Although, in this example, both of the light transmitting conductive layer 18 and the p-side electrode 19 are the electric connecting portion to the p-type layer 16, the light transmitting conductive layer 18 can be the electric connecting portion alone depending material of the wiring film 3, as described later. The electric connecting portion to the n-type layer 14 is the n-side electrode 20.

Then, an insulating film 21 made of SiO₂ or the like is provided on an exposed surface of the semiconductor lamination portion 17 and inside of the separation groove 17a so as to expose surfaces of the upper electrode 19 and the lower electrode 20. As a result, the plurality of the light emitting units 1 separated by the separation groove 17a are formed on the substrate 11. On a surface of the insulating film 21, the n-side electrode 20 of one light emitting unit 1a and the p-side electrode 19 of an light emitting unit 1b adjacent to the light emitting unit 1a are connected with the wiring film 3. The wiring film 3 is formed in a thickness of approximately 0.3 to 1 μm by depositing a metal film of Au, Al or the like by evaporation, sputtering or the like. The wiring film is formed so as to connect each of the light emitting units 1 in a desired manner, in series or parallel.

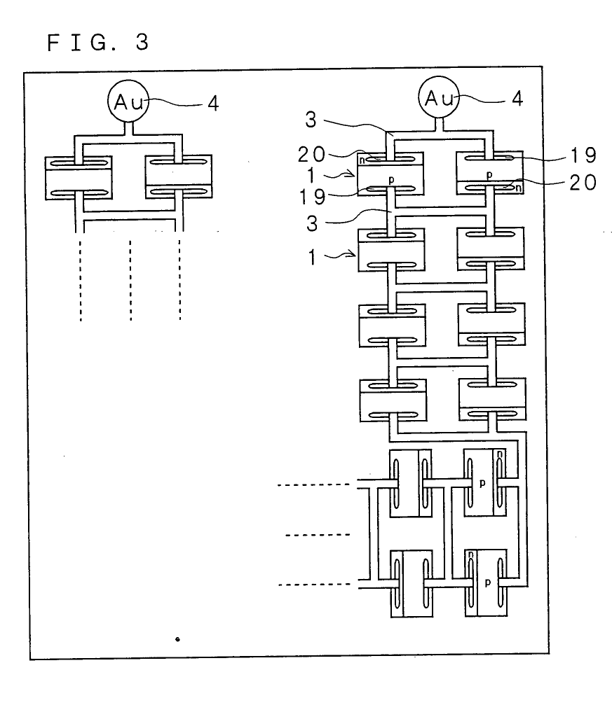

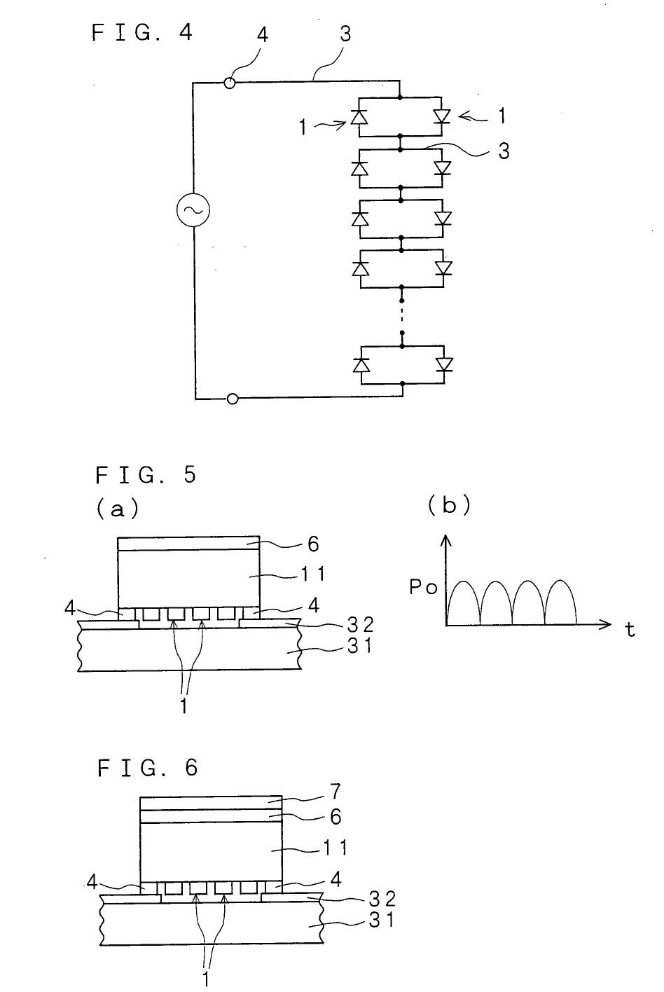

For example, as shown in FIG. 1, a bright light source driven with 100 V AC, a commercial alternative current power source, can be obtained by connecting sequentially the n-side connecting portion 20 of one light emitting unit 1a and the p-side connecting portion 19 of an adjacent light emitting unit 1b, separated by the separation grooves 17a, respectively in order, and by connecting light emitting units to a number of making a total voltage of operation voltages 3.5 to 5 V per one light emitting unit approximately 100 V (a precise adjustment is made by adding a resistor or a capacitor in series), and connecting the groups in parallel in reverse directions of p-side and n-side. As an example of arranging light emitting units 1 is shown in FIG. 3, pairs of light emitting units connected in parallel in reverse direction of p-n junction can be connected in series to a number of making a total operation voltage approximately 100V AC. The above described structure is represented by an equivalent circuit shown in FIG. 4. And if a luminance by this connection is not sufficient, more groups of the same type can be connected in parallel. As shown in FIG. 3, in case of connecting, in series, a set of two light emitting units connected to each other in reverse parallel, it is necessary to connect the n-side electrode 20 and the p-side electrode 19 with the wiring film 3 between the light emitting units adjacent to each other not in a longitudinal direction but in a lateral direction, and a space for forming the wiring film 3 is required between the light emitting units 1. The dummy region 5 described above may be formed in a necessary width for the space.

And next, an explanation on a method for manufacturing the semiconductor light emitting device with a structure shown in FIG. 1 will be given below. The semiconductor lamination portion is formed by a method of metal organic compound vapor deposition (MOCVD), supplying necessary gasses such as a reactant gas like trimethyl gallium (TMG), ammonia (NH₃), trimethyl aluminum (TMA), trimethyl indium (TMI) or the like, and a dopant gas like SiH₄ for making the n-type, or a dopant gas like biscyclopentadienyl magnesium (Cp₂Mg) for making the p-type.

At first, for example, the low temperature buffer layer 12 made of a GaN is deposited with a thickness of approximately 0.005 to 0.1 μm on the sapphire substrate 11, for example, at a temperature of approximately 400 to 600° C., thereafter, a high temperature buffer layer 13 of semi-insulating and made of an un-doped GaN with a thickness of approximately 1 to 3 μm and the n-type layer 14 formed of the GaN layer doped with Si and the AlGaN based compound semiconductor layer doped with Si with a thickness of approximately 1 to 5 μm are formed, at an elevated temperature of for example approximately 600 to 1200° C.

And at a lowered temperature of 400 to 600° C., the active layer 6 is formed which has a structure of a multiple quantum well (MQW) formed with a thickness of approximately 0.05 to 0.3 μm by laminating 3 to 8 pairs of well layers made of, for example, In_{0.13}Ga_{0.87}N and having a thickness of 1 to 3 nm, and barrier layers made of GaN and having a thickness of 10 to 20 nm.

And, elevating a temperature in a growth furnace to approximately 600 to 1200° C., the p-type layer 16 including the p-type AlGaN based compound semiconductor layer and GaN layer are laminated 0.2 to 1 μm thick in total.

Thereafter, by forming a protective film made of Si₃N₄ or the like and annealing at a temperature of approximately 400 to 800° C. and for 10 to 60 minutes to activate the p-type dopant, a light transmitting conductive layer 18 is formed on a surface with, for example, a ZnO layer approximately 0.1 to 0.5 μm thick by a method of MBE, sputtering, evaporation, PLD, ion plating or the like. Successively, in order to form the n-type electrode 20, a part of the semiconductor lamination portion 17 is etched by a method of a reactive ion etching with chlorine gas so as to expose the n-type layer 14. Further subsequently, the semiconductor lamination portion 17 is etched with a width w of approximately 1 μm and reaching the high temperature buffer layer 13 of the semiconductor lamination portion 17, in the vicinity of an exposed portion of the n-type layer 14 and away from an exposed part of the n-type layer 14, in order to separate each of the light emitting units 1 electrically by a dry etching technique similarly. The interval d between the exposed part of the n-type layer 14 and the separation groove 17a is set, for example, approximately 1 μm.

Subsequently, the n-side electrode 20 is formed on the exposed surface of the n-type layer 14 by depositing Ti and Al continuously with a thickness of approximately 0.1 and approximately 0.3 μm respectively by a method of sputtering or evaporating, and by RTA heating at approximately 600° C. for 5 minutes to make an alloy. Then, if the n-side electrode is formed by using a method of lift-off, the n-side electrode of a desired shape can be formed by removing a mask. Thereafter, the insulating film 21 made of SiO₂ or the like is formed on the entire surface and a part of the insulating film 21 is etched and removed so as to expose surfaces of the p-side electrode 19 and the n-side electrode 20. A chip of the semiconductor light emitting device shown in FIG. 3 can be obtained by steps of providing a photo resist film having openings only at connecting positions where the p-side electrode 19 and the n-side electrode 20 exposed are connected, depositing an Au film, Al film or the like by evaporating, forming the desired wiring film 3 by the method of lift-off removing the photo resist film, and dividing a wafer into chips, each of which has a group of light emitting units 1, composed of a plurality of light emitting units. In addition, at a time of forming the wiring films 3, electrode pads 4 for connecting to external power supply are formed of same material as that of the wiring films 3 simultaneously as shown in FIG. 3.

In the example shown in FIG. 1, since the exposed part of the n-type layer 14 for forming the n-side electrode 20 and the separation groove 17a for separating between the light emitting units 1 are formed at different positions even though they are near each other (a width of the dummy region 5 can be widened depending on a purpose), and since, moreover, as the n-side electrode 20 is formed high, it is not necessary that the wiring film 3 connecting the n-side electrode 20 and the p-side electrode 19 between adjacent light emitting units 1, makes connection through a large level difference, even though being formed through the separation groove 17a. In other words, a depth of the separation groove 17a is approximately 3 to 6 μm, but the width is very narrow such as approximately 0.6 to 5 μm, for example approximately 1 μm. Therefor, even if the separation groove 21 is not filled up perfectly, a surface is almost closed and a large level difference does not occur, even some recess is formed, in the wiring film 3. Thereby, problems of a step-coverage never occur and a semiconductor light emitting device provided with a wiring film 3 having very high reliability can be obtained.

In the above-described example, the n-side electrode 20 is formed high so as to expose over the light transmitting conductive layer 18, however in case of not being in the same plane of the p-side electrode 19 by exposing over the light transmitting conductive layer 18, a problem of the level difference does not occur so often because a position of the n-side electrode 20 is smaller than a level difference through the separation groove 17a up to the p-side electrode 19 of adjacent light emitting unit, and because the n-side electrode 20 is connected to the p-side electrode 19 by being laminated with the wiring film 3. Then, even if the n-side electrode 20 is not formed high, disconnection hardly occurs and the wiring film 3 of high stability can be obtained. It is preferable that the n-side electrode is formed high to some extent, because reliability is more improved. Namely, the separation groove 17a may be formed at the substantially same plane so as not to make level difference at a portion of the separation groove 17a.

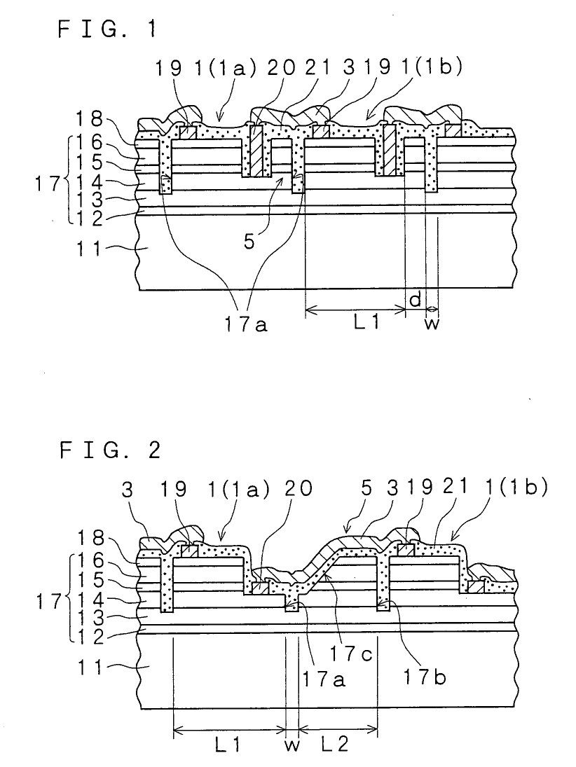

In the above-described example, surfaces of semiconductor layers in both sides of the separation groove 17a are formed in a substantially same plane by forming the separation groove 17a at a different place from the exposed portion of the n-type layer 14, however, even if the separation groove 17a is formed at the exposed portion of the n-type layer 14 exposed, a problem of disconnection can be inhibited by providing a dummy region having an inclined surface (intermediate region). The example is explained by a similar cross-sectional view shown in FIG. 2.

In FIG. 2, as the semiconductor lamination portion 17 is same as that in FIG. 1, same letters and numerals are attached and an explanations are omitted. In this example, the separation groove 17a is formed not from a surface of the semiconductor lamination portion 17 but from the exposed surface of the n-type layer 14 so as to reach the high temperature buffer layer 13. But, the n-type layer 14 is exposed also at an opposite place to a side of forming the n-side electrode 20 intervening the separation groove 17a, and it is characterized in that a dummy region 5 is formed, which has an inclined surface reaching a surface of the light transmitting conductive layer 18 on the semiconductor lamination portion 17 from the n-type layer 14.

The dummy region 5 is formed between one light emitting unit 1a and an adjacent light emitting unit 1b and in a width L2 of approximately 10 to 50 μm. Here, a width L1 of the light emitting unit 1 contributing to light emitting is approximately 60 μm. In addition, in the dummy region 5, the inclined surface 17c is formed from the exposed portion of the n-type layer 14 to the surface of the semiconductor lamination portion 17 as shown in FIG. 2. Although FIG. 2 is not accurate in dimensions but shows only schematic figure of the structure, the level difference between a surface of the light transmitting conductive layer 18 and the n-type layer 14 is approximately 0.5 to 1 μm as described above, and a distance from the exposed surface of the n-type layer 14 to a bottom of the separation groove 17a is approximately 3 to 6 μm. However, as the width w of the separation groove 17a is approximately 1 μm, at least a surface of the separation groove 17a is almost filled up with the insulating layer 21 even if some recess occurs. Then, if the wiring film 3 is formed through the exposed surface of the n-type layer 14 of the dummy region 5, problems of step-coverage can be almost solved, however the inclined surface 17c is formed on a surface of the dummy region 5 in the example shown in FIG. 2. By this, as the insulation film 21 and the wiring film 3 have a gentle slope, reliability of the wiring film 3 can be more improved.

In order to form such inclined surface 17c, masking with a photo resist film or the like except a portion where the inclined surface is formed, and etching with a method of dry etching while inclining the substrate 11 obliquely are carried out, and then the inclined surface 17c shown in FIG. 2 can be formed. After that, the semiconductor light emitting device of a structure shown in FIG. 2 can be formed, in a same manner shown in FIG. 1, by forming the p-side electrode 19 and the n-side electrode 20, forming the insulating film 21 so as to expose surfaces of the electrodes and forming the wiring films 3.

By forming this dummy region 5, besides that the inclined surface 17c described above can be formed, although the dummy region 5 itself does not contribute to emitting light, light emitted at an adjacent light emitting unit 1 and transmitted through semiconductor layers can be radiated from a surface or a side of the dummy region 5, and light emitting efficiency (output to input) can be improved compared to the case that the light emitting units 1 are continuously formed. When the light emitting units 1 are continuously formed, as dissipation of heat generated by energizing is hard, there exists probability of decreasing light emitting efficiency and deteriorating reliability, after all. However, it is preferable to form such dummy region 5 not emitting light from the view point of reliability, because the dummy region does not generate heat but dissipates heat easily. As shown in FIG. 3, in case of connecting two light emitting units 1 arranged in a lateral position with the wiring film 3, a space for forming the wiring film 3 is necessary. Here, the wiring film 3 may be formed on the dummy region 5, and may provide a space to form accessory parts such as an inductor, a capacitor, a resistor (may be used for fitting a series resistance to 100 V operation) or the like. In addition, as there exists a space for forming a wiring film freely, it becomes a merit to form a structure of the light emitting unit 1 itself in a desired shape easily such as a circular shape (shape of a top view) or the like instead of a quadrilateral shape, considering a structure for taking light out. Namely, not only inhibitions of disconnection of a wiring film, but also kinds of merits are accompanied. This way of utilizing the dummy region 5 is same as in an example in FIG. 1.

In the example shown in FIG. 2, between the dummy region 5 and a light emitting unit 1 adjoining at a high side of the semiconductor lamination portion 17, a second separation groove 17b is formed from the surface of the semiconductor lamination portion and reaching to a high temperature buffer layer 13. The second separation groove 17b is also formed at a position where surfaces of the semiconductor lamination portion is in an almost same plane (substantially same plane), and formed in an interval as narrow as possible within a range of capable of separating electrically same as described above, namely approximately 1 μm. Then, if the wiring film 3 is formed on the second separation groove 17b through the insulating film 21, problem of disconnection or the like does not arise. Although the second separation groove 17b may not be formed, electrical separation between adjacent light emitting units 1 can be secured certainly, and reliability of separation is improved by forming the second separation groove 17b, even if the separation groove 17a does not reach the high temperature buffer layer 13 because of variance of etching.

FIG. 5 shows an application example of a semiconductor light emitting device according to the present invention, improving light emitting property. The semiconductor light emitting device according to the present invention has a structure, as described above, in which LEDs are connected to each other in a reverse direction and in which LEDs are operated by alternative current source. Then, a group of LEDs connected in one direction emits light only by a half wave of alternative current, and a group of LEDs connected in another direction emits light only by a left half wave of alternative current. Accordingly, as an output Po to time t is shown in FIG. 5(b), the output of light-emitting is a repetition of output of a half wave, and a pulse of repetition of 100(50×2) Hz or 120(60×2) Hz. Although, such repetition is not noticeable to ordinal human eyes, phenomena of flickering appear still to sensitive eyes. A fluorescent film 6 is provided on a light emitting surface to solve such problem.

In FIG. 5(a), an example of a flip-chip type is shown in which electrode pads 4 formed on a surface of the light emitting device shown in FIG. 1 are connected directly to wirings 32 of a circuit board 31 by soldering. Namely, the example is shown in which mounting is carried out by setting a back surface of a sapphire substrate 11 upward to be a light radiation surface, and by facing a portion where each of light emitting units 1 is connected with a wiring film, not shown in the figure, to the circuit board 31. The fluorescent film 6 is provided on a exposed surface of the sapphire substrate 11. As a sense of incongruity such that it remains light for a long period after switching off arises if the fluorescent has a long afterglow time, the afterglow time (period in which brightness becomes approximately 1/10) is preferable to be 10 msec (millisecond) to approximately 1 sec. For example, ZnS:Cu (ZnS doped with Cu), Y₂O₃, ZnS:Al (ZnS doped with Al) or the like can be employed, and a light emitting device having no flickering can be obtained by coating the surface of the sapphire substrate 11 with such fluorescent material mixed in resin material. However, a place where the fluorescent film 6 is formed is not limited to a back surface of a substrate, and forming at a top surface side may be carried out.

A white light emitting device which is used for incandescent lamps or the like can be obtained by using a light color conversion member ( 1/10 afterglow time of 150 to 200 nsec), for a fluorescent material, such as YAG (Yttrium Aluminum Garnet) converting blue light absorbed to yellow light to make white light by mixing the yellow light and the blue light emitted from a LED chip, or by using a blue LED or an ultraviolet LED and a light color conversion fluorescent which are light color conversion member converting ultraviolet light to red color light, green color and blue color and which are coated with mixing them or independently parting from each other. Then, a semiconductor light emitting device of a desired light color can be obtained while eliminating flickering to eyes by mixing a fluorescent material having an afterglow time of 10 msec or more. Such a fluorescent film maybe provided at a light emitting side of LEDs not limited to the case of forming on a back surface of the sapphire substrate 11, a structure has no limitation.

An example shown in FIG. 6 is a modified example of that shown in FIG. 5, in which a phosphorescent glass film 7 is formed on a surface of the fluorescent film 6. The phosphorescent glass is a glass body mixed with a phosphorescent material such as terbium or the like and can be provided on a desired portion by taking powder of the phosphorescent glass into transparent resin and by coating it. The flickering caused by alternative current drive is eliminated certainly by providing the phosphorescent glass 7, and at the same time the light emitting device can be used for guide lamps and emergency lights at a time of power failures because light remains for 30 to 120 minutes after switching off of an electric power source. Although the phosphorescent glass may be provided directly on LED chips, there is a merit such that absorption of light is reduced by providing on the fluorescent film 6, depending on the fluorescent material when phosphorescent light is main radiation.

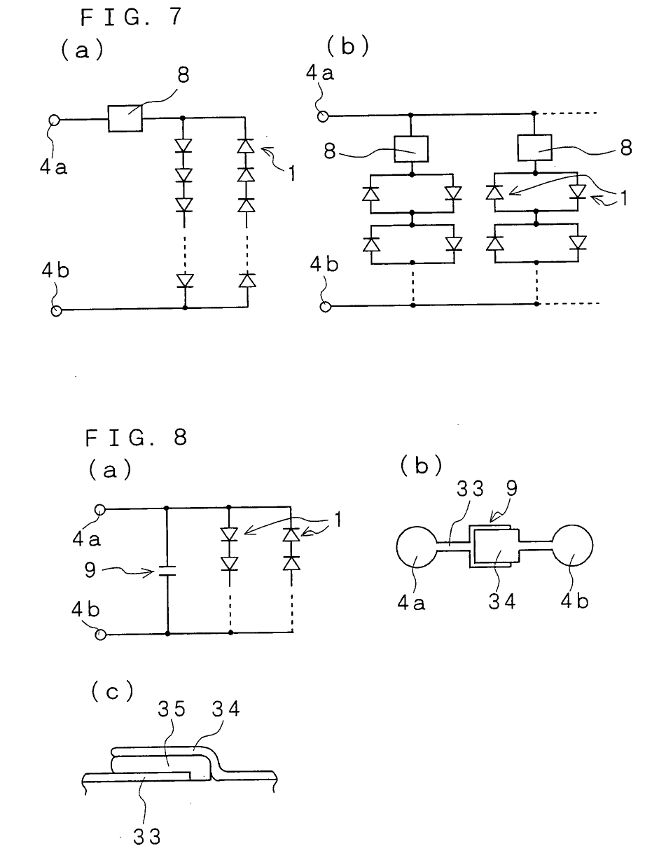

FIG. 7 is a figure showing still another application example of the light emitting device according to the present invention. In ordinary incandescent lamps, a break down of a filament results in not lightening but there is no problem by exchanging of the lamp, however in LEDs failure of a short circuit happens. It may be rare that all LEDs connected in series fail by the short circuit, but it is probable because, when a LED makes a short circuit, applied voltage to other light emitting unit rises. Moreover, as described later, in case of a parallel connection when a part of them fails by a short circuit, other parts of light emitting units do not emit light. Then, as shown in FIG. 7, a fuse element 8 is connected in series to a group of light emitting units 1 (LEDs) connected to each other in series. By this configuration, when a failure of a short circuit happens at a group of LEDs, the fuse element works as a safety device. In order to make a light emitting device brighter while operating with 100 V, a plurality of groups of light emitting units connected in series are further connected in parallel as shown in FIG. 7(b). In this case, by connecting the fuse element 8 to each group of light emitting units connected in series, even if a line of the light emitting units is off, left groups of the light emitting units can emit light and work as an irradiation device even brightness decreases.

FIG. 8 shows an example of a semiconductor light emitting device according to the present invention in which a capacitor 9 is provided as a surge protector protecting the light emitting units when a surge enters. In other words, a capacitor 9 is connected between electrode pads 4a and 4b connected to a group of light emitting units 1 connected in series and/or parallel. The capacitor 9 having a capacitance of, for example, 10 to 20 pF, can protect ordinary electrostatic discharges. As the above-described capacitance is obtained by forming an insulating film 35 made of, for example, Si₃N₄ on the wiring film 33 in a thickness of approximately 5 nm and in an area of 60 μm×60 μm as shown in an explanatory plan view and an explanatory cross-sectional view of FIGS. 8(b) and 8(c), the surge is absorbed once in the capacitor 9 and is discharged while taking time, the light emitting unit can be protected.

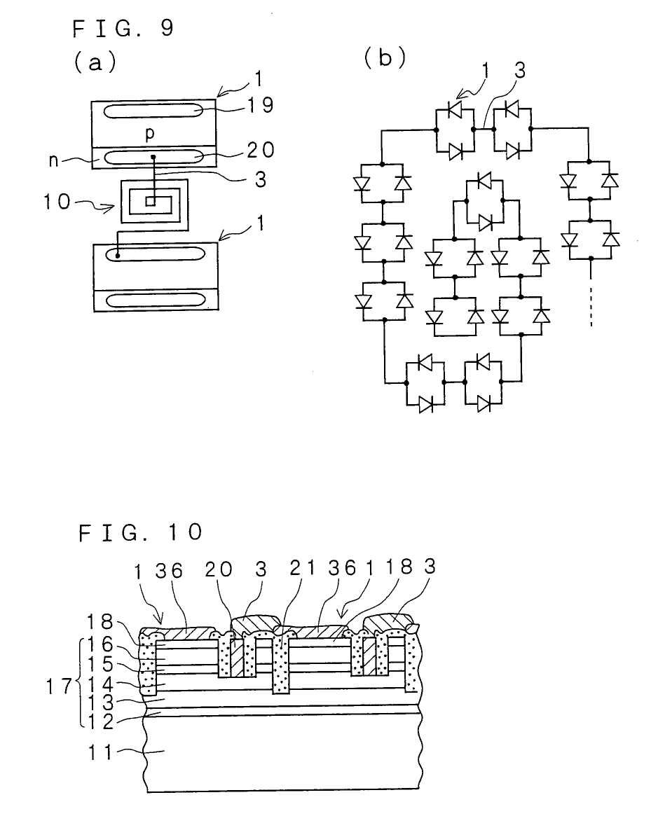

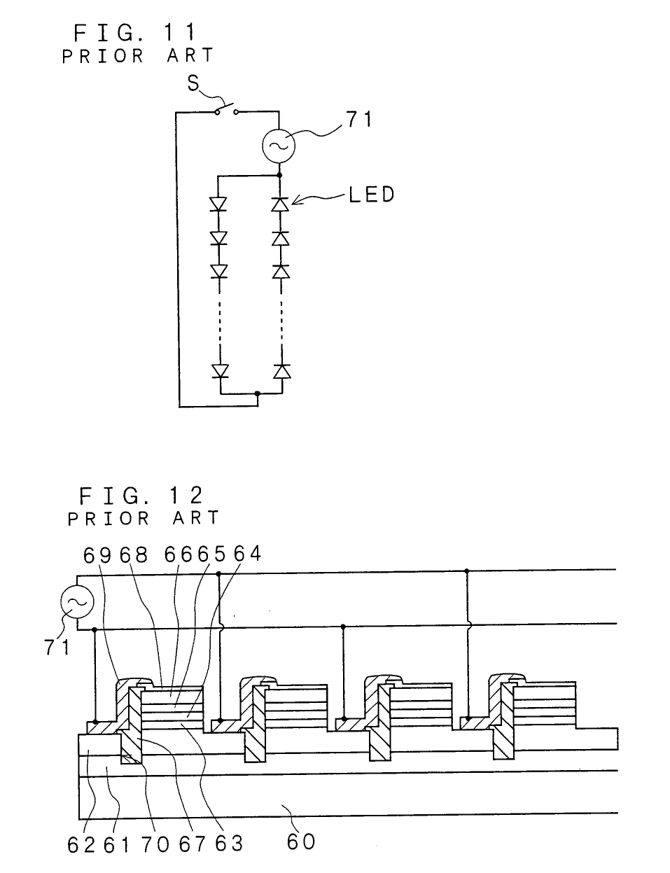

FIG. 9 shows an example of protecting surge by inserting an inductor 10. Namely, FIG. 9(a) shows an example of forming a whirl with the wiring film 3 utilizing a space of a surface of, for example, the above described dummy region 5 shown in FIG. 2. An inductor having an inductance of approximately 1 to 10 nH can be formed by forming such whirl, and the inductor functions to decay the surge, even if the surge enters. The inductor 10 formed between the light emitting units 1 is preferably formed near the electrode pads, and it is not necessary to form between all light emitting units because forming several inductors is sufficient to decay ordinary surges. Here, an end part of a center of the whirl is connected to a light emitting unit of one side with a wiring film provided through an insulating film not shown in the figure.

FIG. 9(b) shows another example of forming a whirl, in which the light emitting units 1 connected in series are connected so as to make the whirl with the wiring film. By connecting the light emitting units 1 of both ends to the electrode pads 4, even if surges enter between the electrode pads, a magnetic field is generated by flowing of a small electric current at a rising of the surge through the light emitting units 1 connected in a whirl shape, and surges can be decayed with an inductance at the time.

FIG. 10 shows a modified example of the present invention to make taking out light emitted at each of the light emitting units 1 easy. Namely, in this example, a wiring film formed on the light emitting unit 1 (on the light transmitting conductive layer 18) is made with a light transmitting conductive layer 36 such as a ZnO layer or the like. It is possible to form all wiring film with the light transmitting conductive layer 36 if a series resistance does not matter because the wiring film 3 is short. However, in case of a long wiring film such as a wiring film forming a inductor, at least the wiring film formed over a light emitting region (portion of the active layer 5 where electric current flows) may be formed with the light transmitting conductive layer 36. The reason is that even ZnO has a higher resistance compared to Au, Al or the like. Emitted light can be taken out efficiently by not providing metal films blocking light at an upper side of a light emitting region.

Although, in each of the above-described examples, an insulating film is formed of SiO₂ or the like by a CVD method, an insulating film filling recesses such as separation grooves and having flatness to some extent can be obtained by forming an insulating film which withstands to a high temperature of approximately 400° C., transparency and insulating property, for example, by employing a product “spinfil 130” manufactured by Clariant Japan K.K. which is processed by spin coating and curing at 200° C. for 10 min and at 400° C. for 10 min. As sharp irregularities on a surface are smoothed because of performing a heat treatment, a wiring film formed on the surface becomes stronger against disconnection and an operation voltage can be preferably lowered because thin parts of the wiring film disappears. However, in this manner if the insulating film is formed too thick, level difference becomes large at a time of forming holes for wiring and problem of disconnection of the wiring film at the level difference arises.

### INDUSTRIAL APPLICABILITY

The light emitting device can be used for kinds of irradiation devices such as ordinary irradiation devices in place of fluorescent lamps by using commercial alternative current power sources and traffic signs or the like.

What is claimed is:

1. A semiconductor light emitting device comprising:
a substrate;
a semiconductor lamination portion formed on the substrate by laminating semiconductor layers so as to form a light emitting layer;
a plurality of light emitting units formed by separating the semiconductor lamination portion electrically into a plurality of units, each of the plurality of light emitting units having a pair of electric connecting portions which are connected to a pair of conductivity type layers of the semiconductor lamination portion, respectively; and
wiring films which are connected to the electric connecting portions for connecting each of the plurality of light emitting units in series and/or parallel,
wherein electrical separation to form the plurality of light emitting units is formed by a separation groove formed in the semiconductor lamination portion and by an insulating film embedded in the separation groove,
wherein the separation groove is formed at a place where surfaces of the semiconductor lamination portions in both sides of the separation groove are in a substantially same plane, and
wherein the wiring film is formed above the separation groove through the insulating film.

2. The semiconductor light emitting device according to claim 1, wherein a dummy region which does not contribute to the light emitting is formed by the semiconductor lamination portion between the separation groove and the light emitting unit of one side of the separation groove.

3. The semiconductor light emitting device according to claim 1,
wherein the electric connecting portions to the pair of conductivity type layers comprise an upper electrode provided so as to connect to a first conductivity type semiconductor layer of an upper layer side of the semiconductor lamination portion, and a lower electrode provided so as to connect to a second conductivity type semiconductor layer of a lower layer exposed by removing a part of the semiconductor lamination portion by etching, and
wherein each of the surfaces of the semiconductor lamination portions in both sides of the separation groove is a semiconductor layer of the upper layer side.

4. The semiconductor light emitting device according to claim 1,
wherein the electric connecting portions to the pair of conductivity type layers comprise an upper electrode provided so as to connect to a first conductivity type semiconductor layer of an upper layer side of the semiconductor lamination portion, and a lower electrode provided so as to connect to a second conductivity type semiconductor layer of a lower layer exposed by removing a part of the semiconductor lamination portion by etching,
wherein each of the surfaces of the semiconductor lamination portions in both sides of the separation groove is a semiconductor layer of a lower layer on which the lower electrode is provided,
wherein a dummy region is formed between a first light emitting unit provided with the lower electrode, and a second light emitting unit provided with the upper electrode to be connected to the lower electrode of the first light emitting unit through the separation groove with the wiring film, and the dummy region has an inclined surface which is formed from the semiconductor layer of the lower layer to the semiconductor layer of the upper layer, and
wherein the wiring film to connect the lower electrode and the upper electrode is formed on the inclined surface.

5. The semiconductor light emitting device according to claim 2, wherein a second separation groove is formed at a portion where both surfaces of the semiconductor lamination portions intervening the second separation groove are in the substantially same plane in an opposite side of the dummy region to the separation groove.

6. The semiconductor light emitting device according to claim 1, wherein the semiconductor lamination portion is made of nitride semiconductor, and a light color conversion member converting a wavelength of light emitted in the light emitting layer to white light is provided at least at a light emitting surface side of the semiconductor lamination portion.

7. The semiconductor light emitting device according to claim 1, wherein the plurality of sets of the light emitting units are connected in series so as to be operated with commercial electric power sources, each of the sets being formed by connecting the electric connecting portions connected to the pair of conductivity type layers of one light emitting unit to electric connecting portions of the other light emitting unit in parallel so as to be reversely connected to each other.

8. The semiconductor light emitting device according to claim 1, wherein a fluorescent material having an afterglow time of 10 msec or more and 1 sec or less is provided at the light emitting surface side of the plurality of light emitting units.

9. The semiconductor light emitting device according to claim 8, wherein the fluorescent material is ZnS:Cu, Y₂O₃ or ZnS:Al.

10. The semiconductor light emitting device according to claim 1, wherein a phosphorescent material having an afterglow time of 1 sec or more is provided at the light emitting surface side of the plurality of light emitting units.

11. The semiconductor light emitting device according to claim 10, wherein the phosphorescent material is terbium.

12. The semiconductor light emitting device according to claim 6, wherein at least one of a fluorescent material having an afterglow time of 10 msec or more and 1 sec or less and a phosphorescent material having an afterglow time of 1 sec or more is mixed with the light color conversion member.

13. The semiconductor light emitting device according to claim 6, wherein the semiconductor lamination portion is formed on a light transmitting substrate; a back surface of the substrate is a surface from which light emitted in the light emitting layer is taken out; and the light color conversion member and at least one of a fluorescent material having an afterglow time of 10 msec or more and 1 sec or less and a phosphorescent material having an afterglow time of 1 sec or more are provided on the back surface of the substrate.

14. The semiconductor light emitting device according to claim 1, wherein a fuse element is connected to each of the groups of the light emitting units connected in series.

15. The semiconductor light emitting device according to claim 1, wherein a capacitor absorbing surges is connected in parallel between a pair of electrode pads, which are connected to an external electric power source, of the plurality of the light emitting units connected in series and/or parallel.

16. The semiconductor light emitting device according to claim 1, wherein an inductor absorbing surges is connected in series between a pair of electrode pads which are connected to an external electric power source of the plurality of the light emitting units connected in series and/or parallel.
